(19) United States
(12) Patent Application Publication
(10) Pub. No.: US 2012/0008442 A1
(43) Pub. Date: Jan. 12, 2012

(54) SEMICONDUCTOR DEVICE AND METHOD OF TESTING THE SAME

(75) Inventor: Mi Sun YOON, Seoul (KR)

(73) Assignee: HYNIX SEMICONDUCTOR INC., Icheon-si (KR)

(21) Appl. No.: 12/982,835

(22) Filed: Dec. 30, 2010

(30) Foreign Application Priority Data
Jul. 9, 2010 (KR) 10-2010-0066493

(51) Int. Cl. G11C 29/00

(52) U.S. Cl. 365/201

(57) ABSTRACT

A semiconductor device according to an aspect of the present disclosure includes a test mode signal generator configured to generate a test mode setup signal, and a controller configured to set a separated test operation in response to the test mode setup signal.

### CROSS-REFERENCE TO RELATED APPLICATION

Priority to Korean patent application number 10-2010-0066493 filed on Jul. 9, 2010, the entire disclosure of which is incorporated by reference herein, is claimed.

### BACKGROUND

Exemplary embodiments relate to a semiconductor device and a method of testing the same and, more particularly, to a method of testing program, read, and erase operations separately, and to a method of testing a partial operation.

A method for testing a semiconductor device may include, for example, a method of using a test circuit arranged in a semiconductor device, a method of controlling major signals used in program, read, and erase operations by using the I/O ports of a semiconductor device, and a method of using an algorithm for testing a specific operation.

The method of using a test circuit may increase the area of a semiconductor device because the test circuit may be included in the semiconductor device. The method of controlling major signals used in various operations may require a number of I/O ports and also may require a complicated signal control technique for controlling the signals. Furthermore, the method of using an algorithm for testing a specific operation may be difficult to test all operations performed in a semiconductor device because it can perform a limited test for a specific operation.

### BRIEF SUMMARY

In accordance with exemplary embodiments of this disclosure, a user selectively tests various operations, performed in a semiconductor device, in response to a test command.

A semiconductor device according to an exemplary embodiment of the present invention includes a test mode signal generator configured to generate a test mode setup signal, and a controller configured to set a separated test operation in response to the test mode setup signal.

A method of testing a semiconductor device according to another exemplary embodiment of the present invention includes selecting any one mode from among a test mode and a user test mode, and performing a separated test operation in response to signals inputted by a user when the user test mode is selected.

### BRIEF DESCRIPTION OF THE DRAWINGS

FIG. 1 is a block diagram illustrating a semiconductor device according to an exemplary embodiment of the present invention.

FIG. 2 is a flowchart illustrating a test method according to an exemplary embodiment of the present invention.

FIG. 3 is a flowchart illustrating a method of testing a program operation according to an exemplary embodiment of the present invention.

FIG. 4 is a flowchart illustrating a method of testing a read operation according to an exemplary embodiment of the present invention.

FIG. 5 is a flowchart illustrating a method of testing an erase operation according to an exemplary embodiment of the present invention.

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the embodiments of the disclosure.

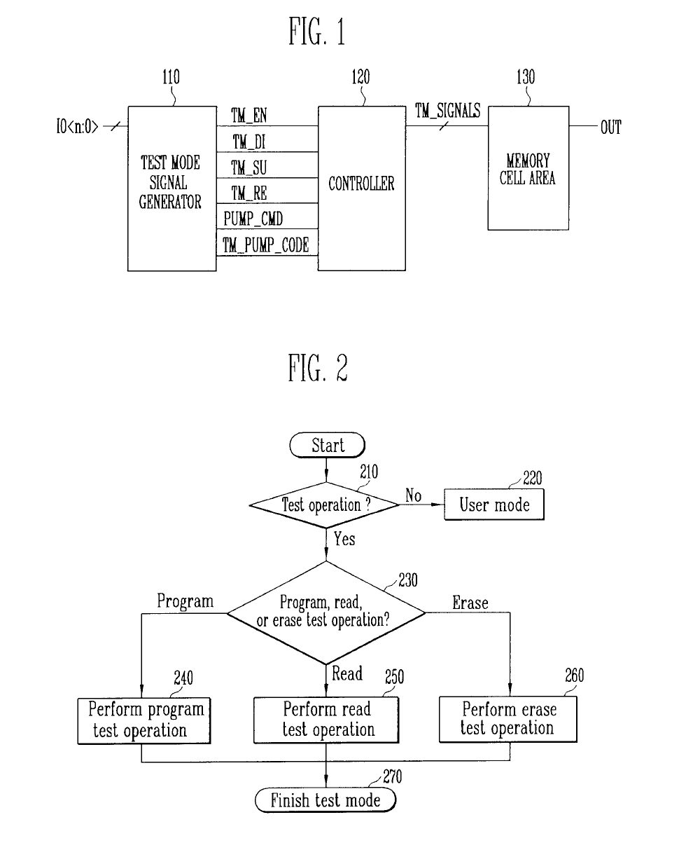

FIG. 1 is a block diagram illustrating a semiconductor device according to an exemplary embodiment of the present invention.

The semiconductor device includes a test mode signal generator 110, a controller 120 and a memory chip 130. The test mode signal generator 110 generates mode signals TM_EN, TM_DI, TM_SU, TM_RE, PUMP_CMD, and TM_PUMP_CODE in response to input signals IO<n:0>. The controller 120 generates signals TM_SIGNALS according to a operation mode including a user mode, a test mode, or a user test mode, in response to the mode signals TM_EN, TM_DI, TM_SU, TM_RE, PUMP_CMD, and TM_PUMP_CODE. A memory cell area 130 is operated in response to the first signals TM_SIGNALS generated by the controller 120. Here, the user mode is a mode in which program, read, and erase operations are performed by a user. The test mode is a mode in which program, read, and erase operations are tested irrespective of a value inputted by a user. The user test mode is a mode in which a separated operation or a partial operation is operated based on a value inputted by a user for a fast and flexible test.

The mode signals generated by the test mode signal generator 110 include the test mode enable signal TM_EN, the test mode disable signal TM_DI, the user test mode signal TM_SU, the test mode restart signal TM_RE, the pump command signal PUMP_CMD, and the pump code TM_PUMP_CODE.

The controller 120 outputs the signals TM_SIGNALS corresponding to the test mode in response to the test mode enable signal TM_EN, outputs the signals TM_SIGNALS corresponding to the user mode in response to the test mode disable signal TM_DI, outputs the signals TM_SIGNALS corresponding to the user test mode in response to the user test mode signal TM_SU, and outputs the signals TM_SIGNALS for switching the user test mode to the test mode in response to the test mode restart signal TM_RE. Furthermore, the pump command signal PUMP_CMD and the pump code TM_PUMP_CODE may be supplied at the same time with the user test mode signal TM_SU. The pump command signal PUMP_CMD and the pump code TM_PUMP_CODE may be supplied to keep the memory cell area 130 in a power-on state while the user test mode is operating.

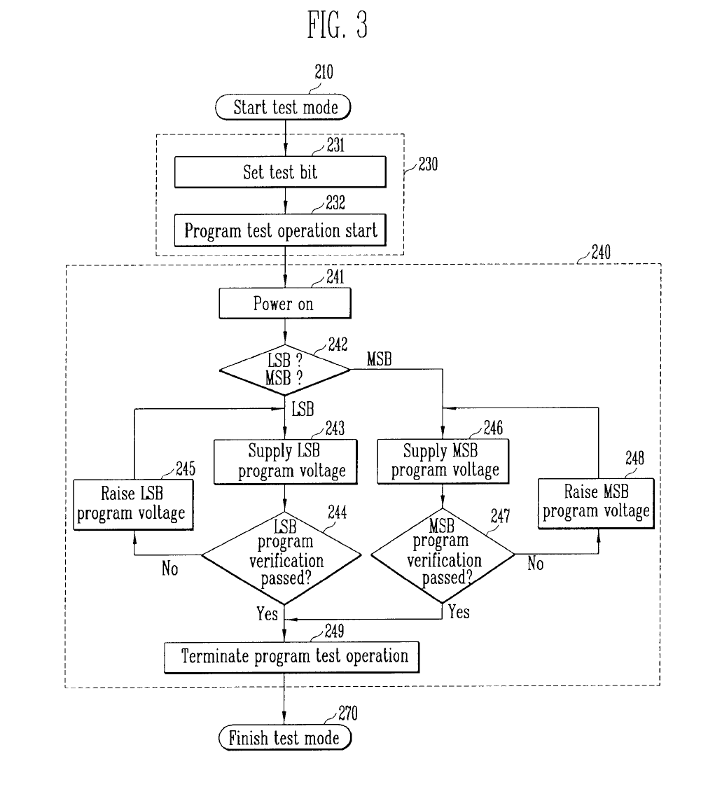

FIG. 2 is a flowchart illustrating a test method according to an exemplary embodiment of the present invention.

When the semiconductor device starts to operate, it determines whether an operation to be performed is a test operation or a common operation at step 210. If, as a result of the determination, the operation to be performed is a common operation, the semiconductor device selects the user mode and performs a program, read, or erase operation on the basis of a value inputted by a user at step 220. Meanwhile, if, as a result of the determination, the operation to be performed is a test operation, the test mode or the user test mode is selected. In the test mode, the semiconductor device performs a program, read, or erase test operation irrespective of a value inputted by a user. However, in the user test mode, a user can test a program, read, or erase operation separately on the basis of a value inputted by a user at step 230, or the user can test a partial operation of the program operation 240, a partial operation of the read operation 250, and a partial operation of the erase operation 260. After the test operation is completed, the test mode is terminated at step 270.

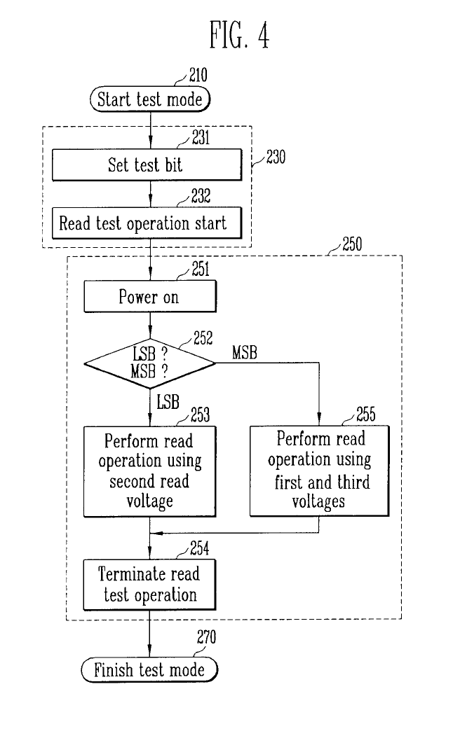

FIG. 3 is a flowchart illustrating a method of testing a program operation according to an exemplary embodiment of the present invention. In particular, this drawing may be understood as a detailed flowchart of the steps 210, 230, 240, and 270 shown in FIG. 2.

Referring to FIG. 3, when the test mode begins at step 210, a bit for the test operation is set at step 231 and a program operation begins at step 232. After the program operation begin, a power enable signal (not shown) is supplied to the memory cell area 130, thereby turning on a power source at step 241.

An exemplary embodiment of a program test operation 240 is described below.

According to an example, if the power source is turned on at step 241, it is determined whether an operation to be performed is a least significant bit (LSB) program operation or a most significant bit (MSB) program operation at step 242. If, as a result of the determination, the operation to be performed is determined to be the least significant bit (LSB) program, a least significant bit (LSB) program voltage is supplied to a selected word line (not shown), thereby raising threshold voltages of selected memory cells (not shown) at step 243. It is then determined whether each of the threshold voltages of all the memory cells on which the least significant bit (LSB) program operation has been performed has reached a target level at step 244. If, as a result of the determination at step 244, there is a memory cell having a threshold voltage not reached the target level, from among the memory cells, the least significant bit (LSB) program voltage is raised at step 245, and a least significant bit (LSB) program operation using the raised LSB program voltage is performed at step 243. Here, the least significant bit (LSB) program operation (steps 243, 244, and 245) is repeatedly performed until each of the threshold voltages of all the memory cells reaches the target level. If, as a result of the determination at step 244, each of the threshold voltages of all the memory cells is determined to have reached the target level, the test for the least significant bit (LSB) program operation is terminated at step 249.

In the step 242 of determining whether the operation to be performed is the least significant bit (LSB) or the most significant bit (MSB) program operation, if the operation to be performed is determined to be the most significant bit (MSB) program, a test operation on the most significant bit (MSB) program is performed in a similar way as the test operation on the least significant bit (LSB) program. More particularly, a most significant bit (MSB) program voltage is supplied to a selected word line, thereby raising threshold voltages of selected memory cells at step 246. Next, it is determined whether each of the threshold voltages of all the memory cells on which the most significant bit (MSB) program operation has been performed has reached a target level at step 247. If, as a result of the determination at step 247, there is a memory cell having a threshold voltage not reached the target level, from among the memory cells, the most significant bit (MSB) program voltage is raised at step 248, and a most significant bit (MSB) program operation using the raised MSB program voltage is performed at step 246. Here, the most significant bit (MSB) program operation (steps 246, 247 and 248) is repeatedly performed until each of the threshold voltages of all the memory cells reaches the target level.

If, as a result of the determination at step 247, each of the threshold voltages of all the memory cells is determined to have reached the target level, the test for the most significant bit (MSB) program operation is terminated at step 249, and the test mode is finished at step 270.

Furthermore, in the user test mode, the least significant bit (LSB) program or most significant bit (MSB) program test may be repeatedly performed within a predetermined number of times on the basis of signals (i.e., IO<n:0> of FIG. 1) inputted by a user. Furthermore, the power source remains turned on because results of the test have to be stored in registers until the test mode is finished at step 270. After the test mode is finished at step 270, the power source may be turned off.

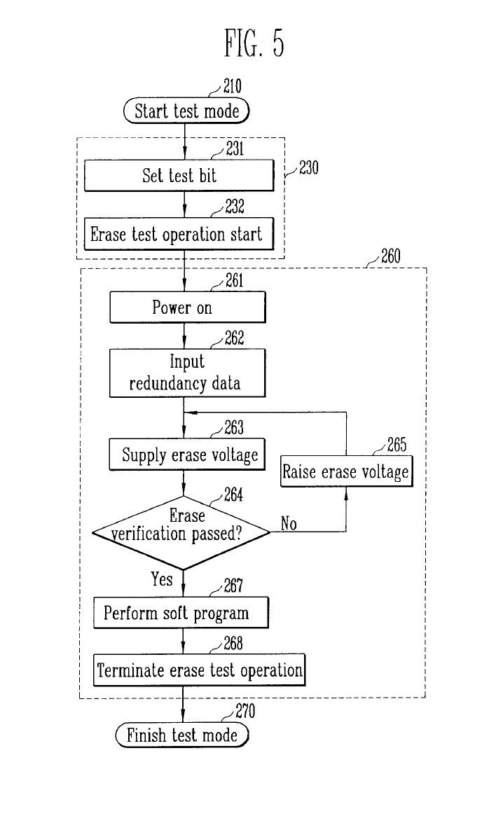

FIG. 4 is a flowchart illustrating a method of testing a read operation according to an exemplary embodiment of the present invention. In particular, this drawing may be understood as a detailed flowchart of the steps 210, 230, 250, and 270 shown in FIG. 2.

Referring to FIG. 4, when the test mode begins at step 210, a bit for the read test operation is set at step 231, and the read test operation begins at step 232. When the test for the read operation is performed, a power enable signal (not shown) is supplied to the memory cell area 130, thereby turning on the power source at step 251.

An exemplary embodiment of the read test operation 250 is described below.

When the power source is turned on at step 251, it is determined whether the least significant bit (LSB) data or the most significant bit (MSB) data will be read at step 252. If, as a result of the determination, the least significant bit (LSB) data is determined to be read, a read operation of reading the least significant bit (LSB) data using a second read voltage is performed at step 253. The second read voltage refers to voltage supplied to a selected word line in order to read memory cells with a second voltage level in a multi-level cell (MLC). After the read operation of reading the least significant bit (LSB) data is performed, the read test operation 250 is terminated at step 254. Meanwhile, if, as a result of the determination at step 252, the most significant bit (MSB) data is determined to be read, a read operation of reading the most significant bit (MSB) data using a first read voltage and a third read voltage is performed on a selected word line at step 255. The first and the second read voltages refer to voltages supplied to a selected word line in order to read memory cells with a first voltage level and a third voltage level respectively, in a multi-level cell (MLC). Here, according to an example, the first voltage level is smaller than the second voltage level, and the second voltage level is smaller than the third voltage level. After the read operation of reading the most significant bit (MSB) data is completed, the read test operation is terminated at step 254.

Furthermore, in the user test mode, the least significant bit (LSB) read operation or the most significant bit (MSB) read operation may be selected in response to signals (i.e., signals IO<n:0>) inputted by a user, or the read operation may be performed on the basis of voltage selected from among the first to third voltages. Furthermore, the power source remains turned on because results of the test have to be stored in registers until the test mode is finished at step 270. After the test mode is finished at step 270, the power source may be turned off.

FIG. 5 is a flowchart illustrating a method of testing an erase operation according to an exemplary embodiment of the present invention. In particular, this drawing may be understood as a detailed flowchart of the steps 210, 230, 260, and 270 shown in FIG. 2.

Referring to FIG. 5, when the test mode begins at step 210, a bit for the erase test operation is set at step 231, and the erase test operation begins at step 232. When the erase test operation is performed, a power enable signal (not shown) is supplied to the memory cell area 130, thereby turning on the power source at step 261.

An exemplary embodiment of the erase test operation 260 is described below.

When the power source is turned on at step 261, redundancy data is inputted to a page buffer (not shown) included in the memory cell area 130 at step 262, and the erase operation is performed by supplying an erase voltage to a well (not shown) at step 263. Next, an erase verification operation is performed to determine whether each of the threshold voltages of memory cells on which the erase operation has been performed is 0 V or lower at step 264. If, as a result of the determination, there is a memory cell having a threshold voltage higher than 0 V, the erase verification operation has not passed, and so the erase operation (steps 263, 264, and 265) is repeatedly performed until each of the threshold voltages of all the memory cells becomes 0 V or lower while gradually raising the erase voltage at step 265. If, as a result of the determination at step 264, each of the threshold voltages of the memory cells is determined to be 0 V or lower, a soft program operation of slightly raising the threshold voltages of the memory cells in the erase state may be performed at step 267, and the erase test operation is then terminated at step 268.

Furthermore, in the user test mode, only the erase operation (steps 263, 264, and 265) may be performed in response to signals (i.e., signals IO<n:0>) inputted by a user, or only the soft program operation (step 267) may be selectively performed. Furthermore, the power source remains turned on because results of the test have to be stored in registers until the test mode is finished at step 270. After the test mode is finished at step 270, the power source may be turned off.

In particular, in the user test mode, a test command may be defined in each of the steps included in the program test operation, the read test operation, and the erase test operation. Accordingly, each of the steps, i.e., a partial operation, may be individually tested, or a test operation may be performed on a combination of the steps.

In accordance with the exemplary embodiments of the present invention, additional circuits for a test operation may not be required. Accordingly, the size of a semiconductor device may not increase, and a user can selectively test all operations implemented in a semiconductor device.

What is claimed is:

1. A semiconductor device, comprising:
a test mode signal generator configured to generate a test mode setup signal; and
a controller configured to set a separated test operation in response to the test mode setup signal.

2. The semiconductor device of claim 1, wherein the test mode setup signals comprise a test mode enable signal, a test mode disable signal, a user test mode signal, a test mode restart signal, and a pump command signal.

3. The semiconductor device of claim 2, wherein the test mode restart signal is used to switch a user test mode to a test mode.

4. The semiconductor device of claim 2, wherein the pump command signal is supplied at the same time with the user test mode signal, and used to keep a power source of a memory cell area turned on when the user test mode is operated.

5. The semiconductor device of claim 1, wherein while the separated test operation is performed, a power source of the memory chip keeps turned on.

6. A method of testing a semiconductor device, comprising:
selecting one mode from among a test mode and a user test mode; and
performing a separated test operation in response to signals inputted by a user when the user test mode is selected.

7. The method of claim 6, wherein the separated test operation comprises a program operation, a read operation, or an erase operation on the basis of a value inputted by a user when the user mode is selected.

8. The method of claim 7, wherein the separated test operation comprises a portion of the program operation.

9. The method of claim 7, wherein the separated test operation comprises a portion of the read operation.

10. The method of claim 7, wherein the separated test operation comprises a portion of the erase operation.

11. The method of claim 6, further comprising setting a test bit on the basis of a value inputted by a user, when the user test mode is selected.

12. The method of claim 7, further comprising defining a test command in each of steps included in the program test operation, the read test operation, or the erase test operation.

13. The method of claim 12, wherein a test operation is performed on the steps, included in the program test operation, the read test operation or the erase test operation, individually or in combination in response to a test command.

14. The method of claim 13, wherein while the test operation is performed in response to the test command, a power source of the memory chip keeps turned on.
